(19) United States
(12) Patent Application Publication
(10) Pub. No.: US 2023/0062671 A1
(43) Pub. Date: Mar. 2, 2023

(54) SUBSTRATE PROCESSING APPARATUS

(71) Applicant: Tokyo Electron Limited, Tokyo (JP)

(72) Inventors: Junnosuke TAGUCHI, Iwate (JP); Yasushi TAKEUCHI, Iwate (JP); Manabu HONMA, Iwate (JP)

(21) Appl. No.: 17/822,249

(22) Filed: Aug. 25, 2022

(30) Foreign Application Priority Data
Sep. 1, 2021 (JP) 2021-142689

(51) Int. Cl. C23C 16/458; C23C 16/46; C23C 16/44

(52) U.S. Cl. CPC C23C 16/4584; C23C 16/46; C23C 16/4408

(57) ABSTRACT

A substrate processing apparatus includes a processing chamber; a rotary table that is rotatably provided in the processing chamber; a heater provided below the rotary table; a partition, provided between the rotary table and the heater with a gap with respect to a lower surface of the rotary table, configured to partition the processing chamber into a first region in which the rotary table is provided and a second region in which the heater is provided; a first processing region in which a first processing gas is supplied to an upper surface of the rotary table; a second processing region in which a second processing gas is supplied to the upper surface of the rotary table; and a separation region in which a separation gas for separating the first and second processing gas is supplied to the upper surface of the rotary table.

### CROSS-REFERENCE TO RELATED APPLICATIONS

This application is based on and claims priority to Japanese Patent Application No. 2021-142689, filed on Sep. 1, 2021, the entire contents of which are incorporated herein by reference.

### BACKGROUND OF THE INVENTION

### 1. Field of the Invention

The disclosure herein relates to a substrate processing apparatus.

### 2. Description of the Related Art

A substrate processing apparatus for depositing various kinds of films on a wafer by rotating a rotary table on which a plurality of wafers are placed to revolve each wafer and repeatedly passing the wafers through a plurality of processing gas supply regions arranged along a radial direction of the rotary table is known (see Patent Document 1). In this apparatus, while the wafers are being revolved by the rotary table, the stage for the wafer is rotated such that the wafer rotates, thereby achieving uniformity of the film in the circumferential direction of the wafer.

### RELATED-ART DOCUMENTS

### Patent Documents

Patent Document 1: Japanese Patent Application Laid-Open No. 2021-111758

### SUMMARY OF THE INVENTION

According to an embodiment of the present disclosure, a substrate processing apparatus includes a processing chamber; a rotary table that is rotatably provided in the processing chamber; a heater provided below the rotary table; a partition, provided between the rotary table and the heater with a gap with respect to a lower surface of the rotary table, configured to partition the processing chamber into a first region in which the rotary table is provided and a second region in which the heater is provided; a first processing region in which a first processing gas is supplied to an upper surface of the rotary table; a second processing region, provided apart from the first processing region in a circumferential direction of the rotary table, in which a second processing gas that is to react with the first processing gas is supplied to the upper surface of the rotary table; and a separation region, provided between the first processing region and the second processing region in the circumferential direction of the rotary table, in which a separation gas that separates the first processing gas and the second processing gas is supplied to the upper surface of the rotary table. The partition is provided such that the gap in at least a part of the separation region is narrower than the gap in the first processing region and the second processing region.

### BRIEF DESCRIPTION OF THE DRAWINGS

FIG. 1 is a cross-sectional view illustrating an example of a substrate processing apparatus according to an embodiment;

FIG. 2 is a plan view (1) illustrating an example of an internal structure of the substrate processing apparatus according to an embodiment;

FIG. 3 is a plan view (2) illustrating an example of an internal structure of the substrate processing apparatus according to an embodiment;

FIG. 4 is a cross-sectional view (1) illustrating an enlarged central portion of a rotary table;

FIG. 5 is a cross-sectional view (2) illustrating an enlarged central portion of a rotary table;

FIG. 6 is a cross-sectional view (3) illustrating an enlarged central portion of a rotary table;

FIG. 7 is a cross-sectional view (4) illustrating an enlarged central portion of a rotary table;

FIG. 8 is a perspective view illustrating an example of a housing box;

FIG. 9 is a cross-sectional view illustrating an example of a housing box;

FIG. 10A and 10B are diagrams illustrating simulation results;

FIG. 11A and 11B are diagrams illustrating simulation results;

FIG. 12A and 12B are diagrams illustrating simulation results; and

FIG. 13A and 13B are diagrams illustrating simulation results.

### DESCRIPTION OF THE EMBODIMENTS

Hereinafter, non-limiting exemplary embodiments of the present disclosure will be described with reference to the accompanying drawings. In all the accompanying drawings, the same or corresponding reference numerals shall be attached to the same or corresponding components and overlapping descriptions may be omitted.

### [Substrate Processing Apparatus]

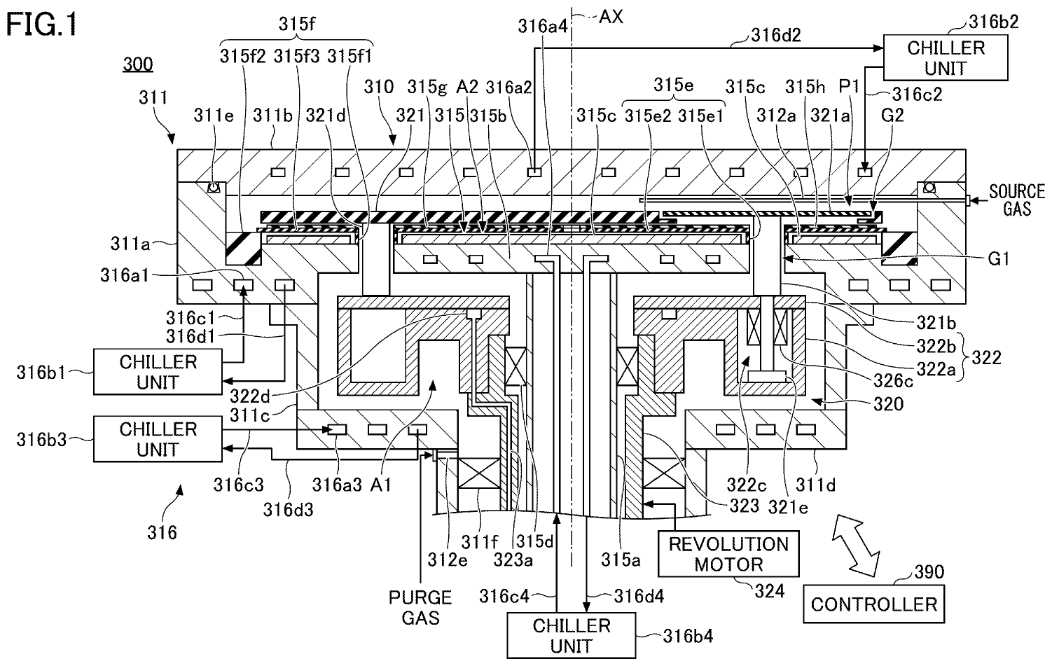

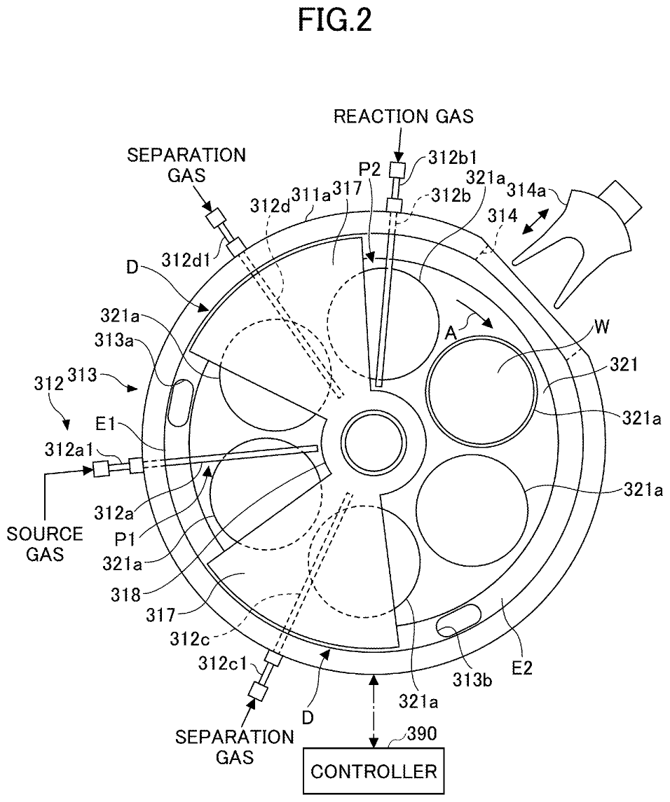

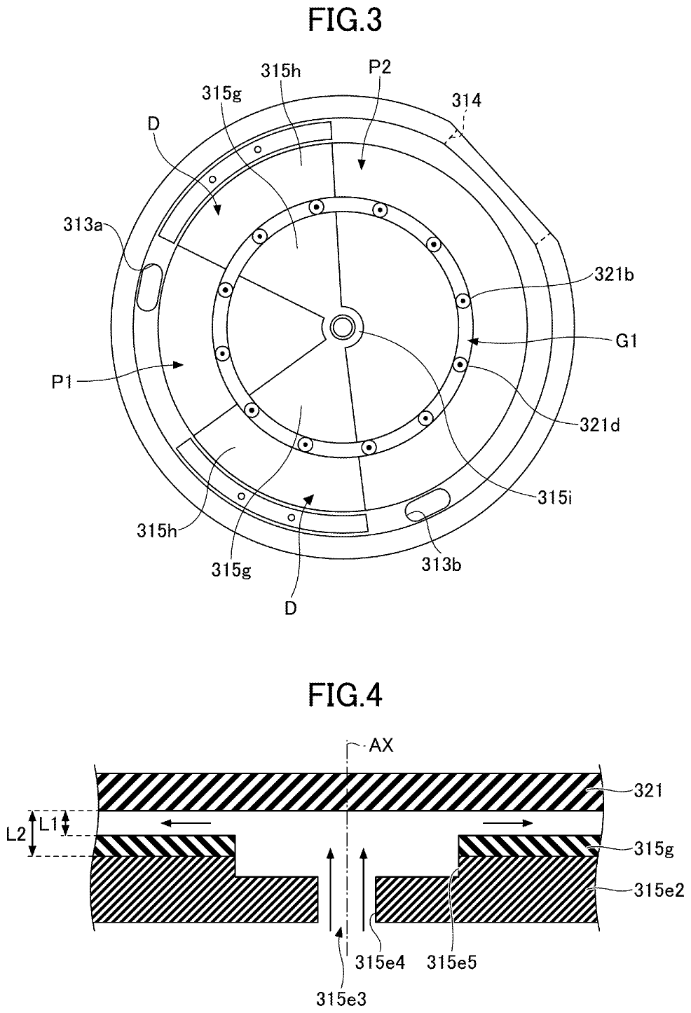

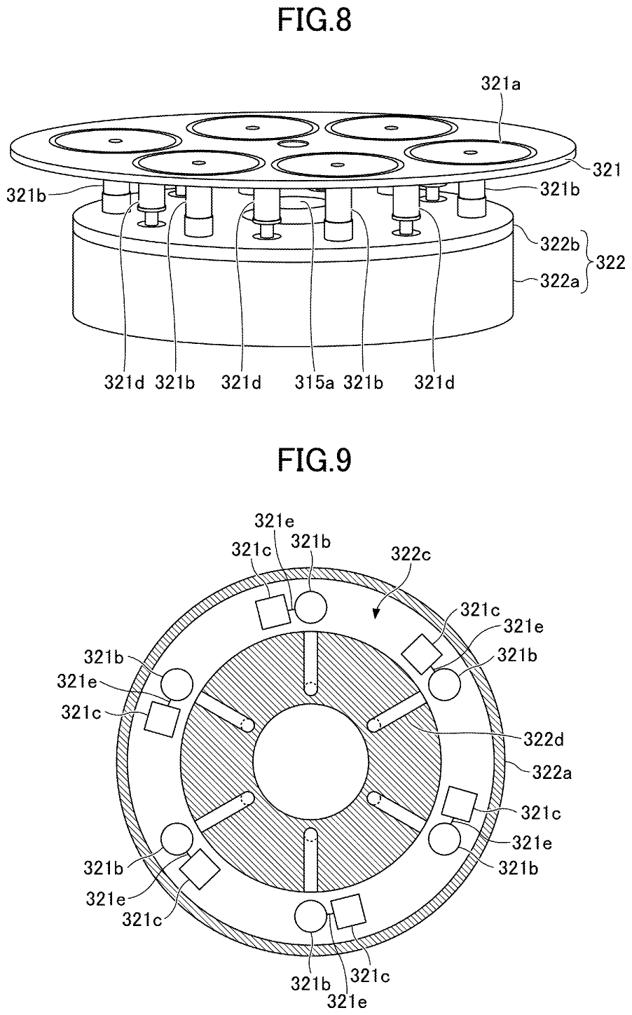

Examples of a substrate processing apparatus according to embodiments will be described with reference to FIG. 1 to FIG. 9. FIG. 1 is a cross-sectional view illustrating an example of a substrate processing apparatus according to an embodiment. FIG. 2 is a plan view illustrating an example of an internal structure of the substrate processing apparatus according to the embodiment, and illustrates the substrate processing apparatus in a state in which the top plate is removed. FIG. 3 is a plan view illustrating an example of the internal structure of the substrate processing apparatus according to the embodiment, and illustrates the substrate processing apparatus in a state in which the top plate and the rotary table are removed. FIG. 4 to FIG. 7 are cross-sectional views illustrating an enlarged central portion of the rotary table. FIG. 8 is a perspective view illustrating an example of a housing box. FIG. 9 is a cross-sectional view illustrating an example of the housing box.

A substrate processing apparatus 300 includes a processor 310, a rotation driving device 320, and a controller 390.

The processor 310 is configured to perform a film deposition process for forming a film on a substrate. The processor 310 includes a processing chamber 311, a gas introduction port 312, a gas exhaust port 313, a transfer port 314, a heater 315, and a cooler 316.

The processing chamber 311 is a vacuum chamber that can reduce air pressure inside the vacuum chamber. The processing chamber 311 has a flat and substantially circular shape. The processing chamber 311 accommodates a plurality of substrates W. The substrate W may be, for example, a semiconductor wafer. The processing chamber 311 includes a body 311a, a top plate 311b, a side wall 311c, and a bottom plate 311d (see FIG. 1). The body 311a has a substantially cylindrical shape. The top plate 311b is airtightly detachably disposed on the upper surface of the body 311a via a seal 311e. The side wall 311c is connected to the lower surface of the body 311a and has a substantially cylindrical shape. The bottom plate 311d is airtightly disposed with respect to the bottom surface of the side wall 311c.

The gas introduction port 312 includes a source gas nozzle 312a, a reaction gas nozzle 312b, separation gas nozzles 312c and 312d, and a purge gas introduction port 312e (see FIG. 1 and FIG. 2).

The source gas nozzle 312a, the reaction gas nozzle 312b, and the separation gas nozzles 312c and 312d are disposed to be spaced apart from each other in the circumferential direction of the processing chamber 311 (a direction indicated by an arrow A in FIG. 2) over the rotary table 321. In the illustrated example, the separation gas nozzle 312c, the source gas nozzle 312a, the separation gas nozzle 312d, and the reaction gas nozzle 312b are arranged clockwise (in the rotational direction of the rotary table 321) from the transfer port 314 in this order. The gas introduction ports 312a1, 312b1, 312c1, and 312d1 (see FIG. 2), which are base end portions of the source gas nozzle 312a, the reaction gas nozzle 312b, and the separation gas nozzles 312c and 312d, are fixed to the outer peripheral wall of the body 311a. The source gas nozzle 312a, the reaction gas nozzle 312b, and the separation gas nozzles 312c and 312d are inserted from the outer peripheral wall of the processing chamber 311 into the processing chamber 311, and are attached so as to extend horizontally with respect to the rotary table 321 along the radial direction of the body 311a. The source gas nozzle 312a, the reaction gas nozzle 312b, and the separation gas nozzles 312c and 312d are formed of, for example, quartz.

The source gas nozzle 312a is connected to a source of a source gas (not illustrated) through a pipe, a flow controller, and the like (not illustrated). The source gas nozzle 312a is provided with a plurality of exhaust holes (not illustrated) opened toward the rotary table 321. The plurality of exhaust holes are arranged to be spaced apart from each other along the length direction of the source gas nozzle 312a. The source gas nozzle 312a discharges the source gas from the plurality of exhaust holes toward the upper surface of the rotary table 321. A region under the source gas nozzle 312a is a source gas adsorption region P1 for adsorbing the source gas on the substrate W. For example, a silicon-containing gas and a metal-containing gas may be used as the source gas.

The reaction gas nozzle 312b is connected to a source of a reaction gas (not illustrated) through a pipe, a flow controller, and the like (not illustrated). The reaction gas nozzle 312b is provided with a plurality of exhaust holes (not illustrated) opened toward the rotary table 321. The plurality of exhaust holes are arranged to be spaced apart from each other along the length direction of the reaction gas nozzle 312b. The reaction gas nozzle 312b discharges the reaction gas from the plurality of exhaust holes toward the upper surface of the rotary table 321. A region under the reaction gas nozzle 312b is a reaction gas supply region P2 in which the source gas adsorbed on the substrate W in the source gas adsorption region P1 is oxidized or nitrided. For example, an oxidizing gas or a nitriding gas may be used as the reaction gas.

The separation gas nozzles 312c and 312d are connected to a supply source (not illustrated) of a separation gas through a pipe, a flow controller, and the like (not illustrated). The separation gas nozzles 312c and 312d are provided with a plurality of exhaust holes (not illustrated) opened toward the rotary table 321. The plurality of exhaust holes are arranged to be spaced apart from each other along the length direction of the separation gas nozzles 312c and 312d. The separation gas nozzles 312c and 312d discharge the separation gas from the plurality of exhaust holes toward the upper surface of the rotary table 321. For example, inert gas such as Ar gas and N₂ gas may be used as the separation gas.

Further, as illustrated in FIG. 2, two protruding portions 317 are provided in the processing chamber 311. The protruding portions 317 are attached to the back surface of the top plate 311b to protrude toward the rotary table 321, so that the protruding portions 317 constitute a separation region D together with the separation gas nozzles 312c and 312d. Further, the protruding portion 317 has a fan-like planar shape whose top is cut in an arc shape such that an inner arc is connected to a protrusion 318 and an outer arc is disposed along the inner peripheral wall of the body 311a of the processing chamber 311.

The purge gas introduction port 312e introduces purge gas into an area A1 surrounded by the body 311a, the side wall 311c, the bottom plate 311d, a fixing shaft 315a, and a heater support 315b (see FIG. 1). For example, the purge gas introduction port 312e is provided below the bottom plate 311d. However, the purge gas introduction port 312e may be provided, for example, such that the purge gas introduction port 312e passes through the side wall 311c, or passes through the bottom plate 311d. Further, for example, multiple purge gas introduction ports 312e may be provided. The purge gas is introduced into the area A1 to maintain the area A1 in the purge gas atmosphere. Further, the purge gas introduced into the area A1 flows into the lower surface side of the rotary table 321 through a gap G1 between the body 311a and the heater support 315b. As a result, the source gas and the reaction gas discharged from the source gas nozzle 312a and the reaction gas nozzle 312b, respectively, and flowing into the lower surface side of the rotary table 321 can be prevented from flowing into the area A1 through the gap G1. For example, inert gas such as Ar gas and N₂ gas may be used as the separation gas.

The gas exhaust port 313 includes a first exhaust port 313a and a second exhaust port 313b (see FIG. 2). The first exhaust port 313a is formed on the bottom of a first exhaust region E1 communicating with the source gas adsorption region P1. The second exhaust port 313b is formed on a bottom of a second exhaust region E2 communicating with the reaction gas supply region P2. The first exhaust port 313a and the second exhaust port 313b are connected to an exhaust device (not illustrated) through an exhaust pipe (not illustrated).

The transfer port 314 is provided on the side wall of the processing chamber 311 (see FIG. 2). In the transfer port 314, the substrate W is transferred between the rotary table 321 in the processing chamber 311 and a transfer arm 314a outside the processing chamber 311. The transfer port 314 is opened and closed by a gate valve (not illustrated).

The heater 315 includes the fixing shaft 315a, the heater support 315b, a heater 315c, a seal 315d, covering members 315e and 315f, and gap adjusting members 315g to 315i (see FIG. 1 and FIG. 3).

The fixing shaft 315a has a cylindrical shape centered on a central axis AX of the processing chamber 311. The fixing shaft 315a is provided inside a revolution shaft 323, which will be described later, so as to penetrate the bottom plate 311d of the processing chamber 311.

The heater support 315b is disposed on the fixing shaft 315a. The heater support 315b has a disc shape and supports the heater 315c. The heater support 315b is provided on the central axis AX side of the processing chamber 311, with respect to the body 311a, with a gap G1 between the body 311a. The gap G1 has an annular shape in a plan view, and forms a revolution orbit in which the rotating shaft 321b and a connector 321d, which will be described later, rotate. The width of the gap G1 is set such that the rotating shaft 321b and the connector 321d do not come into contact with the body 311a and the heater support 315b when the rotating shaft 321b and the connector 321d rotate.

The heater 315c is provided on the body 311a and the heater support 315b. The heater 315c generates heat when power is supplied from a power source (not illustrated) to heat the substrate W.

The seal 315d is provided between the outer peripheral wall of the fixing shaft 315a and the inner peripheral wall of the revolution shaft 323. As a result, the revolution shaft 323 rotates relative to the fixing shaft 315a while maintaining the airtight condition in the processing chamber 311. The seal 315d includes, for example, a magnetic fluid seal.

The covering member 315e includes a side portion 315e1 and a cover portion 315e2. The side portion 315e1 is disposed on the outer edge portion of the heater support 315b along the outer edge portion, straddling the source gas adsorption region P1, the reaction gas supply region P2, and a separation region D. The side portion 315e1 has a cylindrical shape having substantially the same outer diameter as the heater support 315b. The cover portion 315e2 is disposed on the side portion 315e1. The cover portion 315e2 has a disc shape with an outer diameter substantially the same as the outer diameter of the side portion 315e1. The covering member 315e covers the heater 315c on the heater support 315b by the side portion 315e1 and the cover portion 315e2. As a result, the heater 315c on the heater support 315b can be prevented from being exposed to the source gas and the reaction gas discharged from the source gas nozzle 312a and the reaction gas nozzle 312b, respectively, and flowing into the lower surface side of the rotary table 321.

A purge gas supply pipe (not illustrated) for purging an area A2 is provided in the area A2 covered with the covering member 315e. A through hole 315e3 is formed in the center of the cover portion 315e2 (FIG. 4 to FIG. 7). The purge gas supplied into the area A2 from the purge gas supply pipe increases the pressure in the center of the processing chamber 311 where the distance between the source gas adsorption region P1 and the reaction gas supply region P2 is closest. As a result, the source gas and the reaction gas are separated at the center of the processing chamber 311.

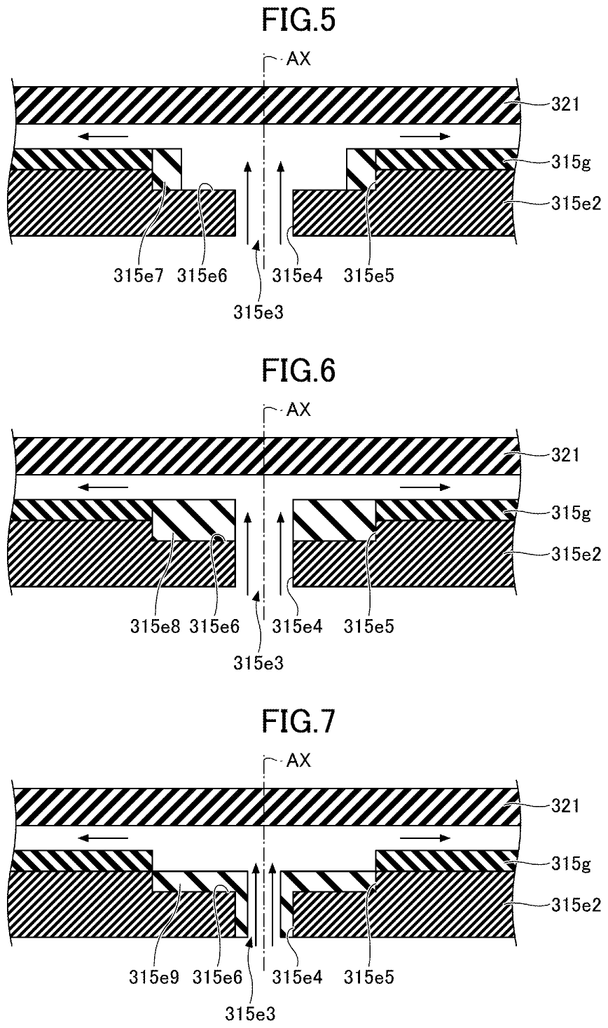

For example, as illustrated in FIG. 4, the through hole 315e3 includes a small diameter portion 315e4 and a large diameter portion 315e5. The small diameter portion 315e4 has a circular shape centered on the central axis AX of the processing chamber 311 in a plan view. The large diameter portion 315e5 is formed on the upper side of the small diameter portion 315e4, and has a circular shape, which is larger than the small diameter portion 315e4, centered on the central axis AX of the processing chamber 311 in a plan view. For example, as illustrated in FIG. 5, an annular attachment 315e7 that narrows the inner diameter of the large diameter portion 315e5 may be provided on a step 315e6 formed by the small diameter portion 315e4 and the large diameter portion 315e5. Further, for example, as illustrated in FIG. 6, an annular attachment 315e8 may be provided on the step 315e6 such that the inner diameter of the large diameter portion 315e5 is narrowed to be equal to the inner diameter of the small diameter portion 315e4. Further, for example, as illustrated in FIG. 7, an annular attachment 315e9 that narrows the inner diameters of the small diameter portion 315e4 and the large diameter portion 315e5 may be provided on the step 315e6. Thus, by changing the inner diameter of the through hole 315e3 using the attachments 315e7 to 315e9, the flow rate of the purge gas flowing out from the area A2 through the through hole 315e3 can be adjusted. As a result, even when the process conditions are different or there is an influence due to a change over time, the retention of the source gas and the reaction gas at the center of the rotary table 321 can be controlled.

The covering member 315f includes an inner portion 315f1, an outer portion 315f2 and a cover portion 315f3. The inner portion 315f1 is disposed on the inner edge portion of the body 311a, so as to straddle the source gas adsorption region P1, the reaction gas supply region P2, and the separation region D along the inner edge portion. The inner portion 315f1 has a cylindrical shape. The outer portion 315f2 is disposed on the outside the position where the inner portion 315f1 is disposed on the body 311a, straddling the source gas adsorption region P1, the reaction gas supply region P2, and the separation region D. The outer portion 315f2 has a cylindrical shape having an inner diameter larger than the outer diameter of the inner portion 315f1. The cover portion 315f3 is disposed on the inner portion 315f1 and the outer portion 315f2. The cover portion 315f3 has a circular plate shape having an inner diameter substantially equal to that of the inner portion 315f1 and an outer diameter larger than that of the outer portion 315f2. The covering member 315f covers the heater 315c on the body 311a with the inner portion 315f1, the outer portion 315f2 and the cover portion 315f3. As a result, the heater 315c on the body 311a can be prevented from being exposed to the source gas and the reaction gas discharged from the source gas nozzle 312a and the reaction gas nozzle 312b, respectively, and flowing into the lower surface side of the rotary table 321.

The gap adjusting member 315g is a plate-shaped member disposed on the cover portion 315e2 in the separation region D. The gap adjusting member 315g has a fan-like planar shape in which the top portion is cut in an arc shape, and is disposed such that an inner arc is connected to the gap adjusting member 315i and an outer arc is along the outer edge of the cover portion 315e2. By disposing the gap adjusting member 315g on the cover portion 315e2, the gap between the lower surface of the rotary table 321 and the upper surface of the cover portion 315e2 is narrowed. As illustrated in FIG. 3, for example, the gap adjusting member 315g is disposed at a position corresponding to the protruding portion 317 on the central axis AX side of the processing chamber 311 with respect to a gap G1. A length L1 of a gap between the upper surface of the gap adjusting member 315g and the lower surface of the rotary table 321 is, for example, not more than half of a length L2 of a gap between the upper surface of the cover portion 315e2 and the lower surface of the rotary table 321 (see FIG. 4). The gap adjusting member 315g is formed of, for example, quartz.

The gap adjusting member 315h is a plate-shaped member disposed on the cover portion 315f3 in the separation region D. The gap adjusting member 315h has a fan-like planar shape in which the top portion is cut in an arc shape, and is disposed such that an inner arc follows the inner edge of the cover portion 315f3 and an outer arc follows the outer arc of the cover portion 315f3. By disposing the gap adjusting member 315h on the cover portion 315f3, the gap between the lower surface of the rotary table 321 and the upper surface of the cover portion 315f3 is narrowed. As illustrated in FIG. 3, for example, the gap adjusting member 315h is disposed at a position corresponding to the protruding portion 317 on the outer peripheral side of the gap G1. A length of a gap between the upper surface of the gap adjusting member 315h and the lower surface of the rotary table 321 is, for example, not more than half of a length of a gap between the upper surface of the cover portion 315f3 and the lower surface of the rotary table 321. The gap adjusting members 315g and 315h are formed of, for example, quartz.

As described above, by disposing the gap adjusting members 315g and 315h respectively on the cover portion 315e2 and 315f3, the gap between the lower surface of the rotary table 321 and the upper surface of the cover portion 315e2 and 315f3 is narrowed. As a result, the pressure in the space between the rotary table 321 and the covering members 315e and 315f in the separation region D is higher than the pressure in the space between the rotary table 321 and the covering members 315e and 315f in the source gas adsorption region P1 and the reaction gas supply region P2. Therefore, in the space between the rotary table 321 and the covering members 315e and 315f, a gas flow from the separation region D toward the source gas adsorption region P1 and the reaction gas supply region P2 is formed. As a result, the source gas and the reaction gas are prevented from being mixed with each other in the space between the rotary table 321 and the covering members 315e and 315f, and the generation of particles caused by the reaction between the source gas and the reaction gas in the space can be prevented.

The gap adjusting member 315g may be formed integrally with the cover portion 315e2, and the gap adjusting member 315h may be formed integrally with the cover portion 315f3. Further, the gap adjusting member 315i may be formed integrally with the gap adjusting member 315g.

The cooler 316 includes fluid flow paths 316a1 to 316a4, chiller units 316b1 to 316b4, inlet pipes 316c1 to 316c4, and outlet pipes 316d1 to 316d4. The fluid flow paths 316a1 to 316a4 are respectively formed inside the body 311a, the top plate 311b, the bottom plate 311d, and the heater support 315b. The chiller units 316b1 to 316b4 output temperature-controlled fluids. The temperature-controlled fluids output from the chiller units 361b1 to 316b4 flow through the inlet pipes 361c1 to 316c4, the fluid flow paths 316a1 to 316a4, and the outlet pipes 316d1 to 316d4 in this order, and circulate. Accordingly, the temperature of each of the body 311a, the top plate 311b, the bottom plate 311d, and the heater support 315b is adjusted. For example, water or fluorinated fluid such as Galden (registered trademark) may be used as a temperature-controlled fluid.

The rotation driving device 320 includes the rotary table 321, a housing box 322, the revolution shaft 323, and a motor 324.

The rotary table 321 is provided in the processing chamber 311. The rotary table 321 rotates around the central axis AX of the processing chamber 311. The rotary table 321 has a disc shape and is made of quartz, for example. On the upper surface side of the rotary table 321, a plurality of (six in the illustrated example) stages 321a are provided along the rotational direction (the circumferential direction) at positions separated from the rotational center of the rotary table 321. The rotary table 321 is connected to the housing box 322 through a connector 321d.

Each stage 321a has a disc shape slightly larger than the substrate W and is made of, for example, quartz. The substrate W is placed on the stage 321a. The stage 321a is connected to a motor 321c via through a rotating shaft 321b and a drive transmission mechanism 321e.

The rotating shaft 321b extends upward from the inside of the housing box 322 through a ceiling 322b and extends to the lower surface of the stage 321a through the gap G1. The upper end of the rotating shaft 321b is connected to the lower surface of the stage 321a, and the lower end thereof is connected to the motor 321c through the drive transmission mechanism 321e. Thus, the rotating shaft 321b transmits the power of the motor 321c to the stage 321a. When the motor 321c rotates, the rotating shaft 321b rotates through the drive transmission mechanism 321e, and the stage 321a rotates relative to the rotary table 321 in response to the rotation of the rotating shaft 321b to rotate the substrate W. When the stage 321a is rotated relative to the rotary table 321 in this manner, particles may be generated due to contact between the rotary table 321 and the stage 321a as the stage 321a rotates. Therefore, in order to prevent the generation of particles, a gap G2 is provided between the rotary table 321 and the stage 321a.

A plurality of rotating shafts 321b are provided along the circumferential direction of the rotary table 321 corresponding to the stage 321a. Each of rotating shafts 321b rotates the corresponding stage 321a relative to the rotary table 321. The plurality of rotating shafts 321b are arranged on the same circumference centered on the center axis AX of the processing chamber 311. A seal 326c is provided in a through hole of a ceiling 322b of the housing box 322, and an airtight condition in the housing box 322 is maintained. The seal 326c includes, for example, a magnetic fluid seal.

The motor 321c rotates the stage 321a relatively to the rotary table 321 through the rotating shaft 321b. The motor 321c may be, for example, a servomotor.

The connector 321d connects the lower surface of the rotary table 321 to the upper surface of the housing box 322. A plurality of connectors 321d are provided along the circumferential direction of the rotary table 321. For example, the number of the connectors 321d is the same as the number of the rotating shafts 321b (six in the illustrated example). In the illustrated example, the plurality of rotating shafts 321b and the plurality of connectors 321d are alternately arranged on the same circumference centered on the central axis AX of the processing chamber 311.

The drive transmission mechanism 321e transmits the power of the motor 321c to the rotating shaft 321b. The drive transmission mechanism 321e includes, for example, a plurality of gears.

The housing box 322 is provided under the rotary table 321 in the processing chamber 311. The housing box 322 is connected to the rotary table 321 through the connector 321d, and is configured to rotate integrally with the rotary table 321. The housing box 322 may be configured to move up and down in the processing chamber 311 via a lifting mechanism (not illustrated). When the housing box 322 moves up and down, the rotary table 321 and the stage 321a move up and down integrally with the housing box 322. As a result, the distance between the substrate W placed on the stage 321a and the source gas nozzle 312a and the reaction gas nozzle 312b is adjusted. The housing box 322 has a body 322a and a ceiling 322b.

The body 322a is formed in a U-shape in a vertical cross-sectional view, and is formed in a ring shape along the rotational direction of the rotary table 321.

The ceiling 322b is provided on the body 322a so as to cover an opening of the body 322a formed in a U-shape in a vertical cross-sectional view. With this configuration, the body 322a and the ceiling 322b form a housing 322c isolated from the inside of the processing chamber 311.

The housing 322c is formed in a rectangular shape in the vertical cross-sectional view, and is formed in a ring shape along the rotational direction of the rotary table 321. The housing 322c houses the motor 321c and the drive transmission mechanism 321e. A communication path 322d that communicates the housing 322c to the outside of the substrate processing apparatus 300 is formed in the body 322a. This causes the atmospheric air to be introduced into the housing 322c from the outside of the substrate processing apparatus 300, and the inside of the housing 322c is cooled down and maintained at atmospheric pressure.

The revolution shaft 323 is fixed to the bottom of the housing box 322. The revolution shaft 323 is provided such that the revolution shaft 323 passes through the bottom plate 311d of the processing chamber 311. The revolution shaft 323 transmits the power of the motor 324 to the rotary table 321 and the housing box 322 to integrally rotate the rotary table 321 and the housing box 322. A seal 311f is provided in a through hole of the bottom plate 311d of the processing chamber 311, and the airtight condition in the processing chamber 311 is maintained. The seal 311f includes, for example, a magnetic fluid seal.

A through hole 323a is formed in the revolution shaft 323. The through hole 323a is connected to the communication path 322d of the housing box 322 and functions as a fluid flow path for introducing atmospheric air into the housing box 322. The through hole 323a also functions as a wiring duct for introducing a power line and a signal line to drive the motor 321c in the housing box 322. For example, the number of the through holes 323a is same as the number of the motors 321c.

The motor 324 rotates the rotary table 321 and the housing box 322 integrally with respect to the fixing shaft 315a through the revolution shaft 323. The motor 324 may be, for example, a servomotor.

The controller 390 controls each unit of the substrate processing apparatus 300. The controller 390 may be, for example, a computer. Further, a computer program that performs an operation of each unit of the substrate processing apparatus 300 is stored in a storage medium. The storage medium may be, for example, a flexible disk, a compact disc, a hard disk, a flash memory, a DVD, or the like.

### [Evaluation Results]

First, in the substrate processing apparatus 300 of the embodiment, a concentration distribution of the source gas on the upper surface side and the lower surface side of the rotary table 321 in a state where the source gas is supplied to the source gas adsorption region P1 and the separation gas is supplied to the separation region D is calculated by simulation.

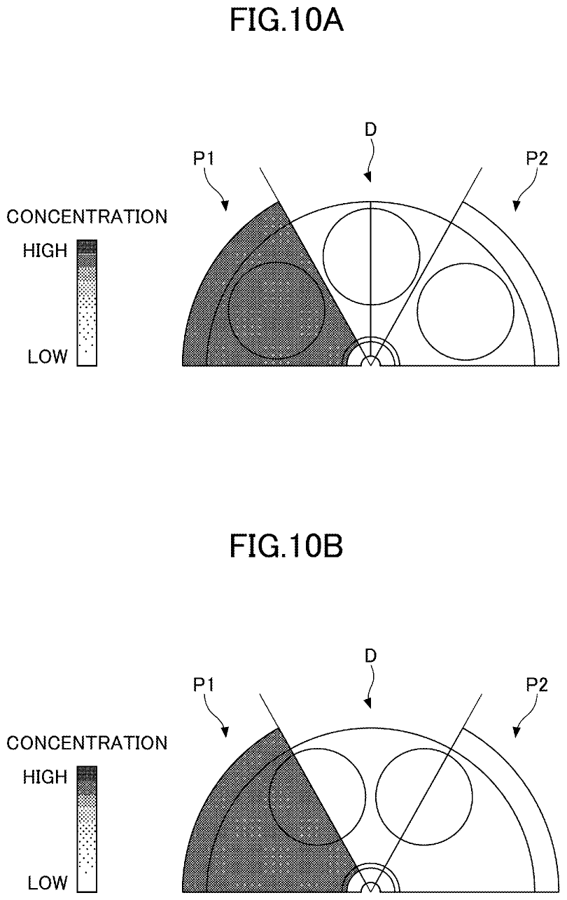

FIG. 10A illustrates the concentration distribution of the source gas on the upper surface side of the rotary table 321 when each stage 321a is located in one region (i.e., the source gas adsorption region P1, the separation region D, and the reaction gas supply region P2). FIG. 10B illustrates the concentration distribution of the source gas on the upper surface side of the rotary table 321 when each stage 321a straddles two adjacent regions.

As illustrated in FIG. 10A, when each stage 321a is located in one region, the source gas supplied to the source gas adsorption region P1 stays in the source gas adsorption region P1 on the upper surface side of the rotary table 321. Further, as illustrated in FIG. 10B, when each stage 321a straddles two regions, the source gas supplied to the source gas adsorption region P1 stays in the source gas adsorption region P1 on the upper surface side of the rotary table 321.

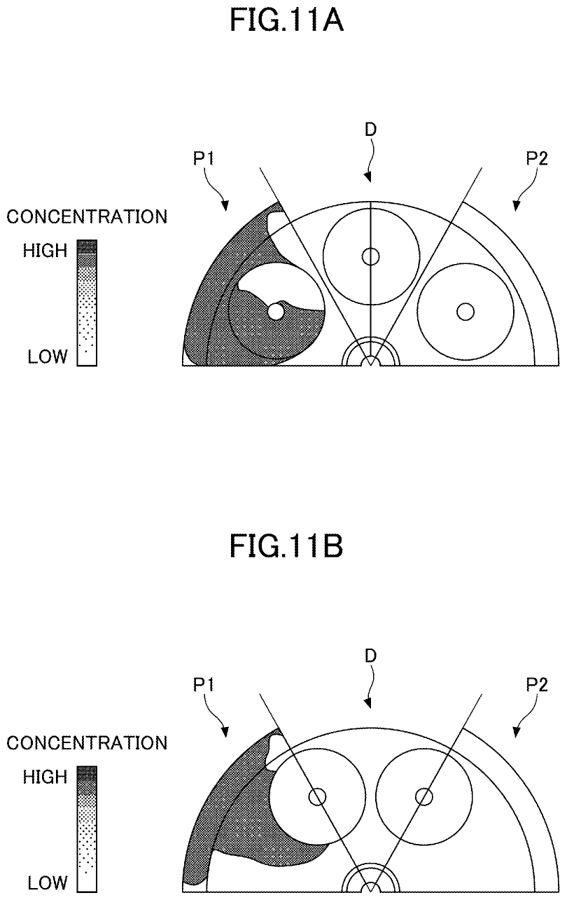

FIG. 11A illustrates the concentration distribution of the source gas on the lower surface side of the rotary table 321 when each stage 321a is located in one region. FIG. 11B illustrates the concentration distribution of the source gas on the lower surface side of the rotary table 321 when each stage 321a straddles two adjacent regions.

As illustrated in FIG. 11A, when each stage 321a is located in one region, the source gas flowing from the upper surface side to the lower surface side of the rotary table 321 through the gap G2 (see FIG. 1) stays in the source gas adsorption region P1 on the lower surface side of the rotary table 321. Further, as illustrated in FIG. 11B, when each stage 321a straddles two regions, the source gas flowing from the upper surface side to the lower surface side of the rotary table 321 through the gap G2 stays in the source gas adsorption region P1 on the lower surface side of the rotary table 321.

Next, in the substrate processing apparatus 300 of the embodiment, the concentration distribution of the reaction gas on the upper surface side and the lower surface side of the rotary table 321 in a state where the reaction gas is supplied to the reaction gas supply region P2 and the separation gas is supplied to the separation region D is calculated by simulation.

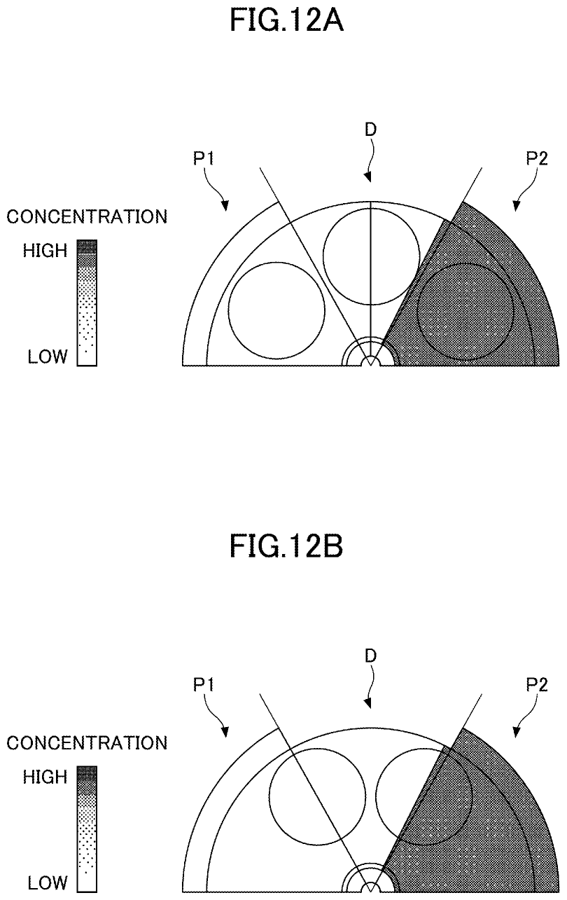

FIG. 12A illustrates the concentration distribution of the reaction gas on the upper surface side of the rotary table 321 when each stage 321a is located in one region. FIG. 12B illustrates the concentration distribution of the reaction gas on the upper surface side of the rotary table 321 when each stage 321a straddles two adjacent regions.

As illustrated in FIG. 12A, when each stage 321a is located in one region, the reaction gas supplied to the reaction gas supply region P2 stays in the reaction gas supply region P2 on the upper surface side of the rotary table 321. Further, as illustrated in FIG. 12B, when each stage 321a straddles two adjacent regions, the reaction gas supplied to the reaction gas supply region P2 stays in the reaction gas supply region P2 on the upper surface side of the rotary table 321.

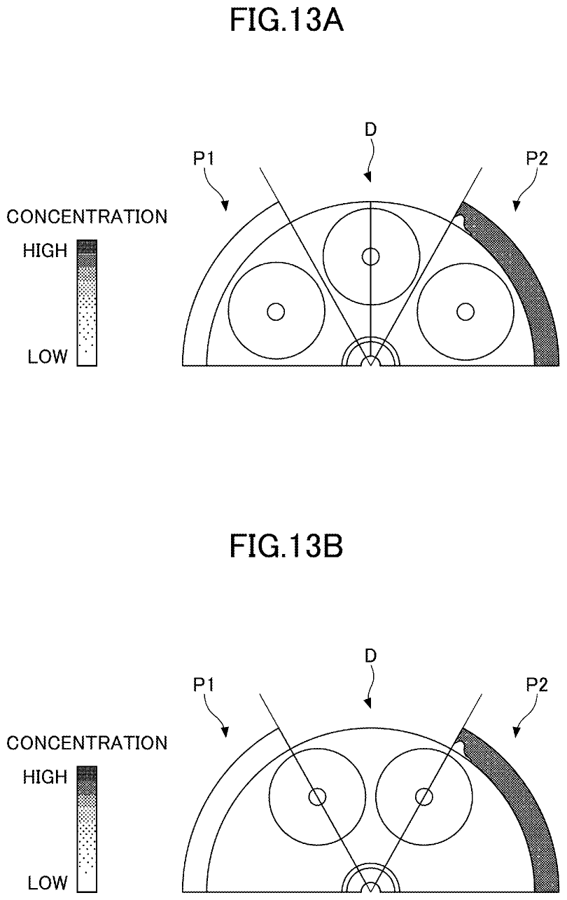

FIG. 13A illustrates the concentration distribution of the reaction gas on the lower surface side of the rotary table 321 when each stage 321a is located in one region. FIG. 13B illustrates the concentration distribution of the reaction gas on the lower surface side of the rotary table 321 when each stage 321a straddles two adjacent regions.

As illustrated in FIG. 13A, when each stage 321a is located in one region, the reaction gas flowing from the upper surface side to the lower surface side of the rotary table 321 through the gap G2 (see FIG. 1) stays in the reaction gas supply region P2 on the lower surface side of the rotary table 321. Further, as illustrated in FIG. 11B, when each stage 321a straddles two adjacent regions, the reaction gas flowing from the upper surface side to the lower surface side of the rotary table 321 through the gap G2 stays in the reaction gas supply region P2 on the lower surface side of the rotary table 321.

From the above simulation results, according to the substrate processing apparatus 300 of the embodiment, the source gas stays in the source gas adsorption region P1 and the reaction gas stays in the reaction gas supply region P2 on both the upper and lower surfaces of the rotary table 321. As a result, it can be said that the mixing of the source gas and the reaction gas is suppressed on both the upper surface side and the lower surface side of the rotary table 321.

In the above embodiment, the source gas is an example of a first processing gas, and the source gas adsorption region P1 is an example of a first processing region. Further, the reaction gas is an example of a second processing gas, and the reaction gas supply region P2 is an example of a second processing region. Further, the covering members 315e and 315f and the gap adjusting members 315g, 315h and 315i are examples of a partition member that partitions a region into two regions, one region being a region where the rotary table 321 is provided and the other region being a region where the heater 315c is provided.

The embodiments disclosed herein should be considered exemplary in all respects and not restrictive. The above embodiments may be omitted, substituted, or modified in various forms without departing from the scope and spirit of the appended claims.

In the above embodiment, six stages 321a are provided on the rotary table 321, but the present disclosure is not limited thereto. For example, the number of the stages 321a may be five or less or seven or more.

In the above embodiment, the case where the processor 310 includes the processing chamber 311, the gas introduction port 312, the gas exhaust port 313, the transfer port 314, the heater 315, and the cooler 316 has been described, but the present disclosure is not limited thereto. For example, the processor 310 may further include a plasma generating unit configured to generate plasma for activating various gases supplied into the processing chamber 311.

What is claimed is:

1. A substrate processing apparatus comprising:
a processing chamber;
a rotary table that is rotatably provided in the processing chamber;
a heater provided below the rotary table;
a partition, provided between the rotary table and the heater with a gap with respect to a lower surface of the rotary table, configured to partition the processing chamber into a first region in which the rotary table is provided and a second region in which the heater is provided;
a first processing region in which a first processing gas is supplied to an upper surface of the rotary table;
a second processing region, provided apart from the first processing region in a circumferential direction of the rotary table, in which a second processing gas that is to react with the first processing gas is supplied to the upper surface of the rotary table; and
a separation region, provided between the first processing region and the second processing region in the circumferential direction of the rotary table, in which a separation gas that separates the first processing gas and the second processing gas is supplied to the upper surface of the rotary table,
wherein the partition is provided such that the gap in at least a part of the separation region is narrower than the gap in the first processing region and the second processing region.

2. The substrate processing apparatus according to claim 1, wherein the partition includes:
a cover that is configured to cover the heater, and to straddle the first processing region, the second processing region, and the separation region; and
a gap adjusting member, disposed on the cover in the separation region, the gap adjusting member configured to narrow the gap.

3. The substrate processing apparatus according to claim 2, wherein a length of a portion of the gap between an upper surface of the gap adjusting member and the lower surface of the rotary table is not more than half of a length of a portion of the gap between the upper surface of the cover and the lower surface of the rotary table.

4. The substrate processing apparatus according to claim 2, wherein the gap adjusting member has a fan-like planar shape.

5. The substrate processing apparatus according to claim 2, wherein the gap adjusting member is formed of quartz.

6. The substrate processing apparatus according to claim 1, further comprising a protruding portion that protrudes toward the rotary table, and is provided on a lower surface of a top plate of the processing chamber in the separation region.

7. The substrate processing apparatus according to claim 1, wherein the rotary table is configured to position a substrate on a stage provided on an upper surface side and to revolve the substrate, and
wherein the rotary table includes a rotating shaft, provided on a lower surface side of the rotary table so as to revolve together with the rotary table, configured to rotate the stage such that the substrate rotates.

8. The substrate processing apparatus according to claim 7, wherein inert gas is introduced toward a lower surface of the stage from underneath the partition in a revolution orbit of the rotating shaft.

9. The substrate processing apparatus according to claim 7, wherein an inert gas is introduced toward a lower surface of the rotary table from underneath the partition at a center of the rotary table.
